(19) United States
(12) Patent Application Publication
(10) Pub. No.: US 2012/0273949 A1
(43) Pub. Date: Nov. 1, 2012

(54) METHOD OF FORMING OXIDE ENCAPSULATED CONDUCTIVE FEATURES

(75) Inventors: Huang Liu, Singapore (SG); Chim Seng Seet, Singapore (SG); Alex Kai Hung See, Singapore (SG)

(73) Assignee: GLOBALFOUNDRIES Singapore Pte. Ltd., Singapore (SG)

(21) Appl. No.: 13/095,140

(22) Filed: Apr. 27, 2011

(51) Int. Cl. H01L 23/52; H01L 21/768

(52) U.S. Cl. 257/751; 438/627; 257/E23.141; 257/E21.575

(57) ABSTRACT

Semiconductor devices are formed with a Cu or Cu alloy interconnect encapsulated by a substantially uniform MnO or Al₂O₃ layer. Embodiments include forming an opening having side surfaces and a bottom surface in a dielectric layer, forming a barrier layer on the side surfaces and the bottom surface of the opening and on an upper surface of the dielectric layer, treating the barrier layer with an oxygen plasma to form dangling oxygen atoms on the barrier layer, depositing a seed layer on the barrier layer, and filling the opening with Cu or a Cu alloy.

### TECHNICAL FIELD

The present disclosure relates to copper (Cu) and/or Cu alloy metallization in semiconductor devices, and to a method for manufacturing semiconductor devices with reliable, low resistance Cu or Cu alloy interconnects. The present disclosure is particularly applicable to forming high speed integrated circuits having submicron design features and high conductivity interconnect structures, including Cu or Cu alloy features substantially uniformly encapsulated with an metallic-oxide layer, such as MnOx or AlOx.

### BACKGROUND

In the manufacture of semiconductors, damscene is applied during metal interconnect back end of line (BEOL) processing. Conventional damascene processing includes forming an opening in an interlayer dielectric and filling the opening with a conductive material, e.g., Cu or a Cu alloy, to form a contact, via, or line. Conventional BEOL processing includes interconnection of individual devices (transistors, capacitors, resistors, etc.) with wiring on the wafer, as well as formation of contacts, insulating layers (dielectrics), metal levels, and bonding sites for chip-to-package connections.

As shown in FIGS. 1A-1F, a conventional damascene process is used to form a metal interconnect in a semiconductor device. FIG. 1A shows a trench 101 formed in a dielectric layer 103.

Due to Cu diffusion through dielectric interlayer materials, such as silicon dioxide, Cu or Cu alloy interconnect structures must be encapsulated by a diffusion barrier layer. FIG. 1B shows a diffusion barrier layer 105 (e.g., Ta/TaN) deposited over the side surfaces 107 and the bottom surface 109 of the trench 101, and over the upper surface 111 of the dielectric layer 103.

A seed layer 113 is deposited over the barrier layer 105 as shown in FIG. 1C. The seed layer 113 may be a Cu, or Cu alloy, such as CuMn or CuAl. FIG. 1D shows Cu or a Cu alloy 115, typically electroplated, filling trench 101 and over seed layer 113.

Planarization, as by chemical-mechanical processing (CMP), is then implemented to remove the Cu or Cu-alloy 115, the seed layer 113, and the barrier layer 105 from dielectric layer 103 and form a substantially planar upper surface, as shown in FIG. 1E.

A capping layer 117, such as a silicon nitride (SiN) or silicon carbon nitride (SiCₓN_{y}), is then deposited, as shown in FIG. 1F.

In FIG. 1F, when employing a Cu alloy seed layer, such as CuMn or CuAl, Mn or Al segregates to the interface between Cu or Cu alloy 115 and capping layer 117. The amount of segregation depends on the Mn or Al concentration in the seed layer 113 and other process conditions. The extent of segregation may result in the seed layer 113 including only Cu, with most of the Mn or Al converted to a metal oxide layer 119, e.g., MnO or Al₂O₃ by reaction with oxygen (O2).

In addition to such interface, segregation occurs at any damaged or defective locations (such as locations with insufficient barrier layer). FIG. 2 shows a conventional Cu or Cu alloy interconnect 201 lined with a barrier layer 203. Conventional practices lead to alloy atoms, such as Mn or Al atoms 205, diffusing toward O₂ to form an oxide layer, e.g., MnO or Al₂O₃, on the upper surface 207 of the Cu or Cu interconnect 201 as well as damaged and defective locations where O₂ is present.

Alloying atoms, such as Mn or Al atoms 205, in the Cu or Cu alloy interconnect 201 easily diffuse toward O₂ to form oxides, e.g., MnO or Al₂O₃, due to its low activation energy. On the other hand, Cu does not react with O₂ to form CuO, where elemental atoms, such as Mn or Al, are present. The resulting oxide layer, e.g., MnO or Al₂O₃, serves as a barrier to prevent: (a) Cu from diffusing along the Cu/SiCNH interface 207 to form CuO; (b) O₂ from diffusing into the Cu interconnect 201 to form CuO; and (c) Mn or Al from continuing diffusion into a dielectric layer 213. Therefore, the electromigration (EM) performance of the interconnect is enhanced.

Damaged and defective locations may be a portion 207 of the barrier layer 203 that is too thin, or a defective interface 211 between the node 201 and dielectric layer 213. The barrier layer 203 should completely surround the entire Cu interconnect 201 to prevent Cu diffusion into and through surrounding materials. Barrier layer 203 should be sufficiently thick to limit Cu diffusivity, thereby chemically isolating interconnect 201 from dielectric layer 213, yet exhibit sufficiently high electrical conductivity to maintain good electronic contact with a conductive line 215. However, barrier layer 203 can be too thin at some locations to limit Cu diffusivity.

Conventional practices only lead to oxide layer, e.g., MnO or Al₂O₃, formation on the upper surface of interconnect 201 or defective/broken liner areas 207, 211, where O₂ is present. However, conventional practices do not result in a substantially uniform oxide barrier layer along sidewalls of the deposited conductive material, e.g., Cu or a Cu alloy, due to the lack of O₂ at such locations.

In advanced nodes such as 20 nm and below, the thickness of the barrier layer (e.g., Ta/TaN, Ru,) is further thinned down to facilitate gap filling and lower conductive line resistance. However, such thinned down barrier layers are not sufficiently strong to withstand EM, stress-migration (SM), or time-dependent dielectric breakdown (TDDB) stressing, and may contain damaged and defective areas therein. Consequently, BEOL reliability performance is degraded.

A need therefore exists for methodology enabling the formation of a substantially uniform metal oxide barrier layer encapsulating a metal interconnect, thereby blocking Cu diffusion and enhancing reliability performance without negatively impacting gap filling.

### SUMMARY

An aspect of the present disclosure is a method of forming a Cu or Cu alloy interconnect encapsulated by a substantially uniform metallic-oxide layer, such as MnO or Al₂O₃, during BEOL processing.

Another aspect of the present disclosure is a semiconductor device including a Cu or Cu alloy interconnect encapsulated by a substantially uniform metallic-oxide layer, such as MnO or Al₂O₃.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method including: forming an opening having side surfaces and a bottom surface in a dielectric layer, forming a barrier layer on the side surfaces and the bottom surface of the opening and on an upper surface of the dielectric layer, treating the barrier layer with an oxygen plasma to form dangling oxygen atoms on the barrier layer, resulting in a seed layer on the barrier layer, and filling the opening with Cu or a Cu alloy.

Aspects of the present disclosure include planarizing, as by CMP, to remove the barrier layer, seed layer, and Cu or Cu alloy from the upper surface of the dielectric layer, such that the upper surface of the inlaid Cu or Cu alloy is substantially coplanar with the upper surface of the dielectric layer. Further aspects include providing a capping layer, such as a SiN or SiCₓN_{y}, on the Cu or Cu alloy filling the opening. Additional aspects include depositing a Cu alloy seed layer, such as CuMn or CuAl, resulting in the formation of a metal oxide layer, e.g., a MnO or Al₂O₃. Other aspects include depositing the barrier layer at a thickness of 5 Å to 100 Å. Another aspect includes depositing the seed layer at a thickness of 100 Å to 500 Å. In accordance with further aspects, the metal oxide layer is formed at a thickness of 5 Å to 20 Å.

Another aspect of the present disclosure is a device including: a semiconductor element, a dielectric layer over the semiconductor element, a Cu or Cu alloy filling an opening in the dielectric layer, and a metal oxide layer encapsulating the Cu or Cu alloy filling the opening.

Aspects include devices including inlaid Cu or Cu alloy encapsulated by an oxide layer, e.g., a MnO or Al₂O₃ layer, having a substantially uniform thickness of 5 Å to 20 Å. Aspects include devices having Cu or a Cu alloy inlaid in a trench with a barrier layer at a thickness of 5 Å to 100 Å.

Another aspect of the present disclosure is a method including: providing a dielectric layer over a semiconductor element; forming a trench having side surfaces and a bottom surface in the dielectric layer; depositing a barrier layer on the side surfaces and the bottom surface of the trench; treating the barrier layer with an oxygen plasma to form dangling oxygen bonds on the barrier layer; depositing a Cu alloy seed layer on the barrier layer; filling the trench with copper (Cu) or a Cu alloy to form a Cu or Cu alloy inlay and an overburden on an upper surface of the dielectric layer; and planarizing such that an upper surface of the Cu or Cu alloy inlay is substantially coplanar with the upper surface of the dielectric layer, resulting in a metal oxide layer encapsulating the Cu or Cu alloy inlay.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawing and in which like reference numerals refer to similar elements and in which:

FIGS. 1A through 1F schematically illustrate a conventional damascene process for forming a metal interconnect in a semiconductor device;

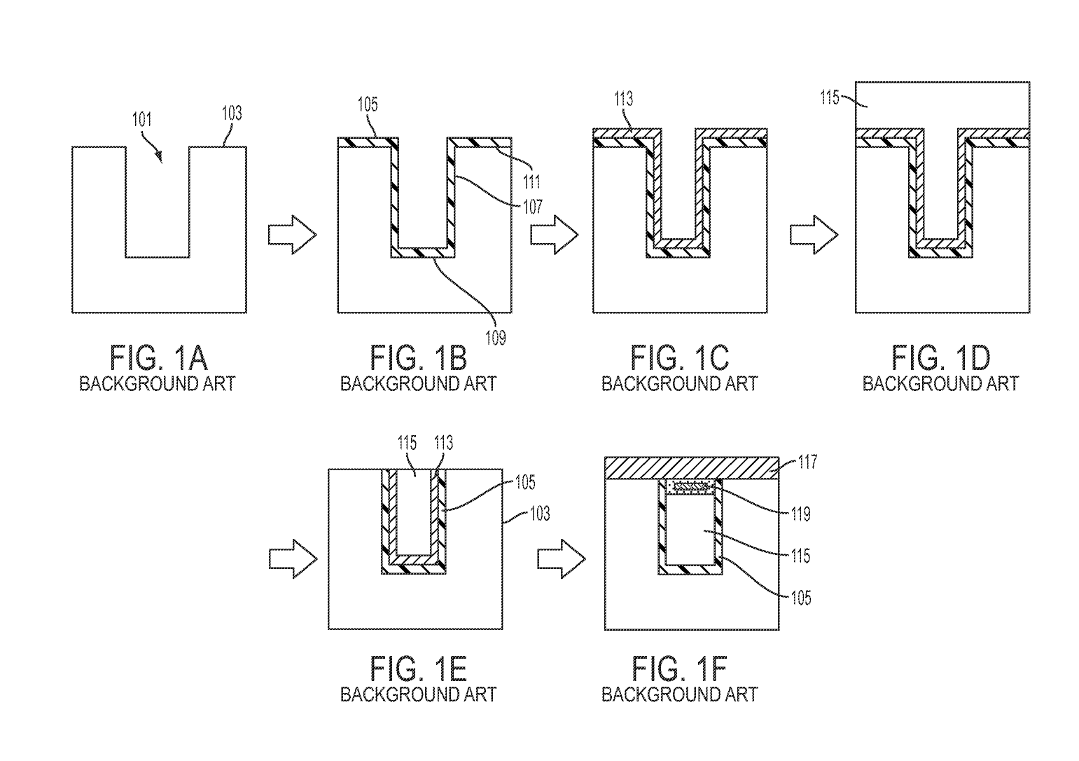

FIG. 2 schematically illustrates a conventional interconnect lined with a barrier layer; and

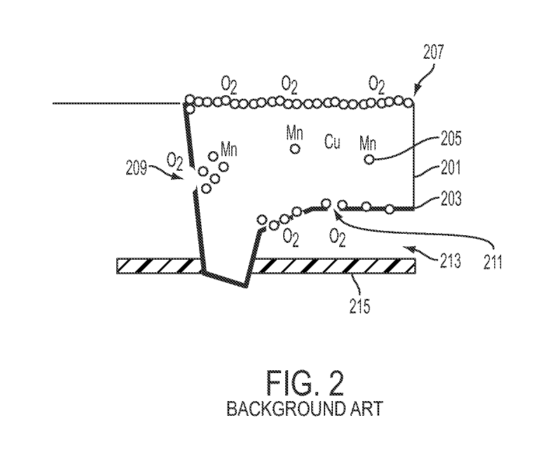

FIGS. 3A through 3F schematically illustrate a process flow for forming a metal interconnect in a semiconductor device in accordance with an embodiment of the present disclosure.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the problematic BEOL reliability performance, particularly as the thickness of barrier liners is reduced to accommodate gap filling and low line resistance. The present disclosure addresses and solves such problems by providing methodology enabling the formation of a substantially uniform metallic-oxide layer, e.g., a MnO or Al₂O₃ layer, encapsulating a metal interconnect, e.g., a Cu or Cu alloy contact, via, or line, thereby preventing Cu diffusion into and through dielectric layers and, consequently, enhancing reliability performance without negatively impacting gap filling.

Methodology in accordance with embodiments of the present disclosure includes forming an opening having side surfaces and a bottom surface in a dielectric layer, forming a barrier layer on the side surfaces and the bottom surface of the opening and on an upper surface of the dielectric layer, treating the barrier layer with an oxygen plasma to form dangling oxygen atoms on the barrier layer, depositing a seed layer on the barrier layer, and filling the opening with Cu or Cu alloy.

Still other aspects, features, and technical effects of blocking Cu diffusion from a Cu or Cu alloy interconnect without negatively impacting gap filling will be readily apparent to those skilled in this art from the following detailed description, wherein preferred embodiments are shown and described, simply by way of illustration of the best mode contemplated. The disclosure is capable of other and different embodiments, and its several details are capable of modifications in various obvious respects. Accordingly, the drawings and description are to be regarded as illustrative in nature, and not as restrictive.

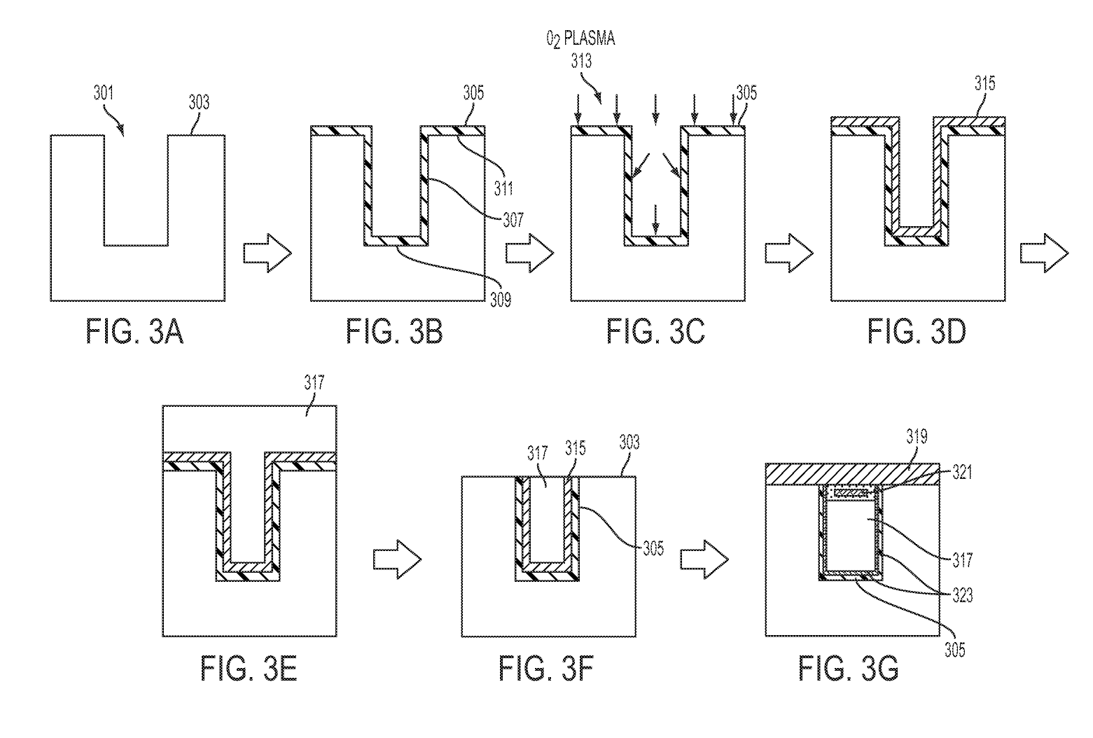

FIGS. 3A-3F illustrates methodology in accordance with an embodiment of the present disclosure. Adverting to FIG. 3A, an opening, e.g., trench 301, is formed in dielectric layer 303 by, e.g., reactive ion etching (RIE).

A diffusion barrier layer 305 is formed over the side surfaces 307 and bottom surface 309 of trench 301, and over the upper surface 311 of the dialectic layer 303 by, e.g., physical vapor deposition (PVD), as illustrated in FIG. 3B. Barrier layer 305 may be formed at a thickness of 5 Å to 100 Å. Typical diffusion barrier metals include tantalum (Ta), tantalum nitride (TaN), ruthenium (Ru), cobalt (Co), or Ta/TaN.

Adverting to FIG. 3C, the resulting structure is treated with an oxygen plasma 313, as for 30-180 seconds, at an RF power of 400-900 W, pressure of 15-35 m Torr, 100-400° C., and an ozone (O3) flow rate of 60-120 sccm. Treatment with the oxygen plasma forms dangling oxygen atoms in the barrier layer 305 along the side walls 307 and bottom surface 309 of trench 30. Such dangling oxygen atoms later react to form an encapsulating oxide barrier.

Adverting to FIG. 3D, a seed layer 315 is deposited over barrier layer 305 by, e.g., physical vapor deposition (PVD). The seed layer 315 may be formed to a thickness of 100 Å to 500 Å, and may include a Cu alloy, such as CuMn or CuAl. CuAl seed layers increase the EM life time by a factor of ten compared with a Cu seed layer, while CuMn seed layers increase the EM life time by a factor of one hundred compared with a Cu seed layer,

A conductive material, such as Cu or a Cu alloy 317, is deposited, as by electrochemical plating, electroless plating, or chemical vapor deposition, to fill trench 301 and form an overburden 317 on dielectric layer 302, as illustrated in FIG. 3E. Planarization, as by CMP, is then implemented to remove the overburden 317, and barrier layer 305 and seed layer 315 from the upper surface of dielectric layer 301 forming a substantially planar upper surface, as illustrated in FIG. 3F.

A capping layer 319 is subsequently deposited, as by chemical vapor deposition (CVD). Capping layer 319 may include SiN or SiCₓN_{y}.

Alloying metal atoms in seed layer 315, e.g., Mn or Al segregate to the previously formed dangling oxygen atoms to form an encapsulating oxide layer, e.g., MnO or Al₂O₃. The amount of segregation depends on the Mn or Al concentration in the Cu alloy seed layer and various process conditions. In some embodiments, segregation is sufficient to result in a substantially Cu seed layer, such that substantially all of the Mn or Al segregates to form a substantially uniform encapsulating MnO or Al₂O₃ oxide layer 321. Typically, such a protective oxide layer forms before Cu or Cu alloy deposition. EDX/EELS analysis confirms that the dangling oxygen bonding can fully oxidize Mn or Al atoms from the seed layer of a thickness of 5 Å to 20 Å to form a substantially uniform MnO or Al₂O₃ encapsulating layer.

Embodiments of the present disclosure can achieve several technical effects, including blocking Cu diffusion from a Cu or Cu alloy interconnect thereby enhancing EM life time without negatively impacting gap filling. The present disclosure enjoys industrial applicability in any of various types of highly integrated semiconductor devices.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

What is claimed is:

1. A method comprising:
forming an opening having side surfaces and a bottom surface in a dielectric layer;
forming a barrier layer on the side surfaces and the bottom surface of the opening and on an upper surface of the dielectric layer;
treating the barrier layer with an oxygen plasma to form dangling oxygen atoms on the barrier layer;
depositing a seed layer on the barrier layer; and
filling the opening with copper (Cu) or a Cu alloy,
resulting in a metal oxide layer is formed on upper and bottom surfaces and along side surfaces of the Cu or Cu alloy filling the opening.

2. The method according to claim 1, comprising removing the barrier layer, the seed layer, and the Cu or Cu alloy from the upper surface of the dielectric layer.

3. The method according to claim 2, comprising forming a capping layer on the Cu or Cu alloy filling the opening.

4. The method according to claim 3, wherein the capping layer comprises silicon carbon nitride (SiCₓN_{y}).

5. The method according to claim 1, comprising depositing a Cu alloy as the seed layer.

6. The method according to claim 5, comprising depositing a CuMn or CuAl alloy as the seed layer, wherein the metal oxide layer comprises MnO or Al₂O₃.

7. The method according to claim 1, comprising depositing the barrier layer at a thickness of 5 Å to 100 Å.

8. The method according to claim 1, comprising depositing the seed layer at a thickness of 100 Å to 500 Å.

9. The method according to claim 1, wherein the metal oxide layer is formed at a thickness of 5 Å to 20 Å.

10. A device comprising:
a semiconductor element;
a dielectric layer over the semiconductor element;
Cu or a Cu alloy filling an opening in the dielectric layer; and
a metal oxide layer encapsulating the Cu or Cu alloy filling the opening.

11. The device according to claim 10, wherein the metal oxide layer comprises MnO or Al₂O₃.

12. The device according to claim 10, further comprising a barrier layer lining the opening.

13. The device according to claim 10, wherein the metal oxide layer has a substantially uniform thickness of 5 Å to 20 Å.

14. The device according to claim 10, wherein the barrier layer has a thickness of 5 Å to 100 Å.

15. The device according to claim 10, wherein:
the opening is a trench; and
the Cu or Cu alloy filling the trench is a conductive line.

16. A method comprising:
providing a dielectric layer over a semiconductor element;
forming a trench having side surfaces and a bottom surface in the dielectric layer;
depositing a barrier layer on the side surfaces and the bottom surface of the trench;
treating the barrier layer with an oxygen plasma to form dangling oxygen atoms on the barrier layer;
depositing a Cu alloy seed layer on the barrier layer;
filling the trench with copper (Cu) or a Cu-alloy to form a Cu or Cu-alloy inlay and an overburden on an upper surface of the dielectric layer; and
planarizing such that an upper surface of the Cu or Cu alloy inlay is substantially coplanar with the upper surface of the dielectric layer,
resulting in a metal oxide layer is formed encapsulating the Cu or Cu alloy inlay.

17. The method according to claim 16, comprising depositing a CuMn alloy or a CuAl alloy as the seed layer.

18. The method according to claim 17, wherein the metal oxide layer comprises MnO or Al₂O₃.

19. The method according to claim 16, comprising depositing the barrier layer at a thickness of 5 Å to 100 Å.

20. The method according to claim 16, wherein the metal oxide layer is formed at a thickness of 5 Å to 20 Å.
